(19) United States
(12) Patent Application Publication
(10) Pub. No.: US 2024/0069656 A1
(43) Pub. Date: Feb. 29, 2024

(54) KNOB SCREEN DEVICE

(71) Applicant: (SHENZHEN WIRELESS-TAG TECHNOLOGY CO., LIMITED), ShenZhen, Guangdong (CN)

(72) Inventors: Zhougang WEN, Shenzhen, Guangdong (CN); Youjun LENG, Shenzhen, Guangdong (CN); Yanbin GU, Shenzhen, Guangdong (CN); Leyu WANG, Shenzhen, Guangdong (CN); Hui ZOU, Shenzhen, Guangdong (CN); Yunxiang MU, Shenzhen, Guangdong (CN); Hui LI, Shenzhen, Guangdong (CN); Honggang WANG, Shenzhen, Guangdong (CN)

(21) Appl. No.: 18/259,574

(22) PCT Filed: May 14, 2021
(86) PCT No.: PCT/CN2021/093750

§ 371 Date: Jun. 27, 2023

(30) Foreign Application Priority Data
Apr. 30, 2021 (CN) 202120927076.4

(51) Int. Cl. G06F 3/0362; H03K 17/90

(52) U.S. Cl. CPC G06F 3/0362; H03K 17/90

(57) ABSTRACT

The knob screen device includes a glass touch cover plate, a display screen, a screen support frame, a semi-transparent turning structure, an annular light-leading friction shim, at least one battery, a mainboard and a magnetic attraction assembly. The knob screen device further comprises: at least one Hall sensor provided on the mainboard; at least one multicolor LED ambient light provided on the mainboard; and at least one annular multipolar flexible magnet provided in the semi-transparent turning structure. The semi-transparent turning structure is connected to external component by means of the magnetic attraction assembly. In this way, the knob screen device is simple in structure, low in cost, easy to process and install and more flexible in application circumferences.

### TECHNICAL FIELD

The present invention relates to the technical field of knob screens, especially a knob screen device.

### BACKGROUND TECHNOLOGY

With the rapid development of the electronics industry, knob screens are widely used in many products such as 86-type switch boxes, temperature controllers, clothes washing machines, microwave ovens.

However, with the increasing requirement from the consumers on operation experiences, deficiencies of conventional knob screen devices such as complicated structures, poor sensitivity, complex installation procedures and high manufacturing difficulties become prominent.

For knob screens of rolling friction structures that are quite novel, there are disadvantages such as easy-wearing of the rollers, being not durable, involving high expenses and high manufacturing difficulties. Therefore, design of knob screen devices is still to be improved.

### SUMMARY OF THE INVENTION

In view of the foregoing technical problems, the present invention provides a knob screen device, aiming to address the deficiencies of existing knob screens, such as being of complex structure, poor sensitivity, sophisticated installation procedures and high manufacturing difficulties.

To address the foregoing technical problems, the present invention proposes a knob screen device. The knob screen device comprises: a glass touch cover plate, a display, a display support, semi-transparent turning structure, a mainboard and a magnetic attraction assembly, wherein the knob screen device comprises further: at least one Hall sensor, provided on the mainboard; and at least one annular multipolar flexible magnet, provided in the semi-transparent turning structure.

Further, an annular groove is provided in the semi-transparent turning structure and is configured to fix the annular multipolar flexible magnet.

Further, the at least one Hall sensor and the annular multipolar flexible magnet are provided at a same side of the mainboard.

Further, an annular light-leading friction shim is provided in between the semi-transparent turning structure and the mainboard, so that colorful LED light at an outer circumference of the mainboard can be mixed and guided to the semi-transparent turning structure to serve as ambient light.

Further, a feedback vibration motor is provided on the mainboard and the feedback vibration motor is located at the same side as the at least one Hall sensor.

Further, the magnetic attraction assembly comprises: a magnetic attraction panel, with an adapted dimension and shape with the mainboard; a magnetic attraction seat, provided on the magnetic attraction panel.

Further, the magnetic attraction assembly comprises further a magnetic attraction pedestal adapted to 86-type switch boxes, and the magnetic attraction pedestal is detachably connected with the 86-type switch boxes; and an offline voice identification module and a temperature and humidity sensor are provided on the magnetic attraction pedestal.

Further, an annular reflective structure is formed in between the magnetic attraction panel and the magnetic attraction pedestal so as to enhance reception of sound signals.

A plurality of holes are provided on the magnetic attraction pedestal and annular extrusions adapted to the plurality of holes are provided on the magnetic attraction panel.

Further, at least one step screw is provided on the magnetic attraction assembly, and the at least one step screw passes the annular extrusions and the plurality of holes to fix the mainboard and the display support.

Beneficial effects of the present invention: different with the prior art, the knob screen device according to the present invention makes use of the annular multipolar flexible magnet to engage with the Hall sensor in the mainboard, every turning the device for an angle of a magnetic pole or changing the turning direction, the Hall sensor will recognize corresponding pulse signals so as to realize accurate and friction loss free control, and by using the magnetic attraction assembly, installation and detachment of the entire device is simple and quick, in this way the device can be used in more circumstances.

### BRIEF DESCRIPTION OF DRAWINGS

To illustrate the technical solutions in embodiments of the present invention or the prior art to a better degree, hereinafter the drawings to be used in description of the embodiments or the prior art will be briefly introduced, obviously, the drawings given here show only some embodiments of the present invention and for those of ordinary skill in the art, without paying inventive effort, other drawings can be obtained based on the structures shown in the accompanying drawings.

FIG. 1 is an exploded diagram showing a knob screen device according to the present invention;

FIG. 2 is a diagram showing installation of the knob screen device according to the present invention;

Markups in the drawings are:

Glass touch cover plate 01, display 02, display support 03, semi-transparent turning structure 04, annular groove 42, annular multipolar flexible magnet 05, battery 06, annular light-leading friction shim 07, mainboard 08, feedback vibration motor 09, Hall sensor 10, magnetic attraction assembly 11, magnetic attraction panel 112, annular extrusion 1122, magnetic attraction seat 114, magnetic attraction pedestal 116, step screw 118, hole 1162, 86-type multifunctional circuit board 12, power panel 13, multicolor LED ambient light 14.

Realization, functions, characteristics and advantages of the present invention will be further explained in conjunction with the embodiments and the drawings.

### EMBODIMENTS

Hereinafter the technical solutions in the embodiments of the present invention will be described completely and clearly in conjunction with the drawings accompanying the embodiments of the present invention, apparently, the described embodiments are only some of the embodiments of the present invention, rather than all. Based on the embodiments in the present invention, all other embodiments obtained by those of ordinary skill in the art without paying inventive effort fall into the protection scope of the present invention.

It is noteworthy that, all directional indications in the embodiments such as upper, lower, left, right, front, rear . . . are used to explain relative spatial relationships, moving conditions between the parts as shown in the drawings in a specific gesture, and when changes occur to the specific gesture, the directional indications change accordingly.

Furthermore, in the present invention, usage of terms such as “first”, “second” is only for description purposes, and shall not be construed to indicate or imply relative importance or indicate implicitly the amount of the features. Hence, features limited by “first” and “second” can indicate or imply at least one of the features. Further, the technical solutions in the embodiments can be mutually combined to the extent that those of ordinary skill in the art can realize, when combination of the technical solutions results in contradiction or cannot be realized, it shall be considered that such combination of the technical solutions doesn't exist and doesn't fall into the protection scope of the present invention.

A technical solution provided in the present invention is to provide a knob screen device.

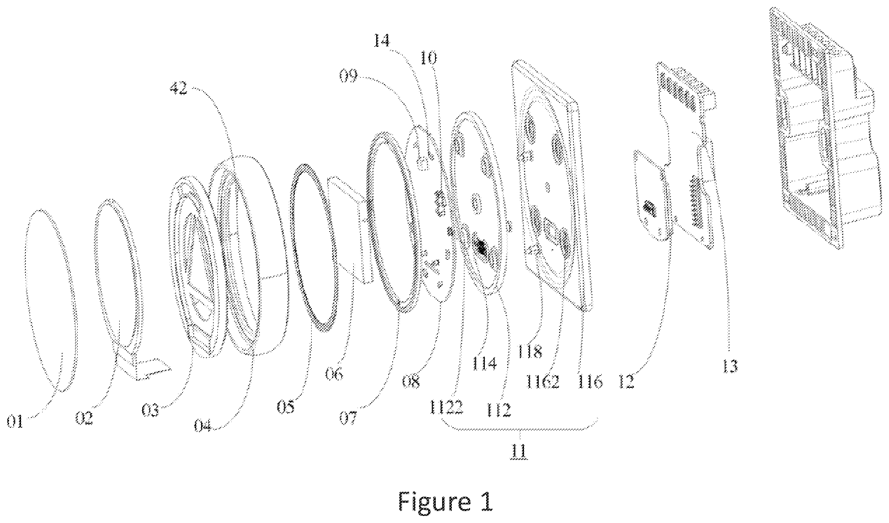

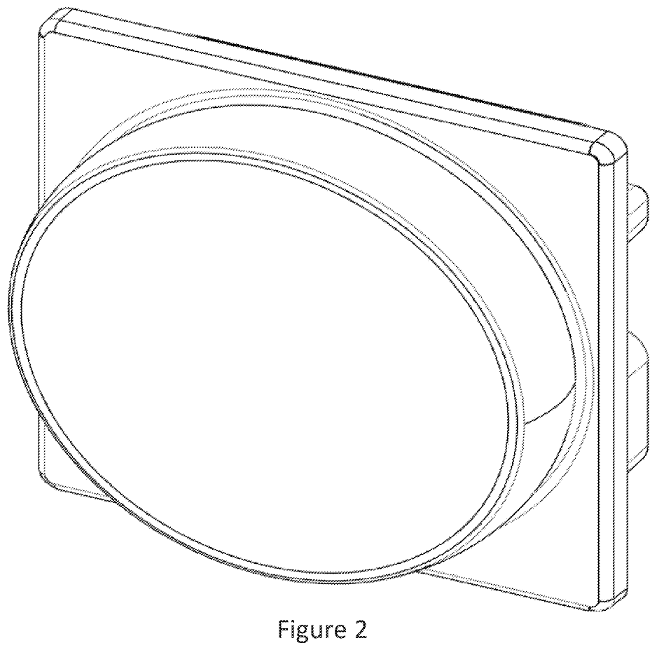

Please refer to FIGS. 1-2, FIG. 1 is an exploded view of the knob screen device as provided in the present invention.

FIG. 2 is a diagram showing assembly of the knob screen device as provided in the present invention.

The knob screen device comprises: a glass touch cover plate 01, a display 02, a display support 03, a semi-transparent turning structure 04, at least one battery 06, a mainboard 08 and a magnetic attraction assembly 11, the knob screen device comprises further: at least one Hall sensor 10, provided on the mainboard 08, at least one annular multipolar flexible magnet 05, provided in the semi-transparent turning structure 04; at least one multicolor LED ambient light 14, provided on the mainboard; wherein the semi-transparent turning structure 04 is connected with the magnetic attraction assembly 11 by magnetic attraction.

Further, the display support 03 is compatible with a plurality of circular or rectangular display assembly.

Further, an annular light-leading friction shim 07 is provided in between the semi-transparent turning structure 04 and the mainboard 08, usually such friction shim comprises light-guiding plastic. Ambient light effects can be achieved by mixing evenly lights from the multicolor LED ambient light 14 around the mainboard 08 and passing the lights through the semi-transparent turning structure 04.

Alternatively, an annular groove 42 is provided in the semi-transparent turning structure 04, for fixing the at least one annular multipolar flexible magnet 05. It is comprehensible that, design the annular groove 42 can have the at least one annular multipolar flexible magnet 05 properly enclosed therein, so as to fix the at least one annular multipolar flexible magnet 05 to a better extent, and when the semi-transparent turning structure 04 is turned, the at least one annular multipolar flexible magnet 05 can turn accordingly more sensitively.

Generally, two Hall sensors are provided on the mainboard 08, and the Hall sensors are provided at the same side of the mainboard as the at least one annular multipolar flexible magnet 05. Further, the Hall sensor 10 is provided with a dual latch, so as to identify the turning direction of the at least one annular multipolar flexible magnet 05 and the quantity of the magnet poles. As the at least one annular multipolar flexible magnet 05 is multipolar, once turned for a magnet pole, the Hall sensor 10 will detect a pulse signal, when a direction of the at least one annular multipolar flexible magnet 05 is changed, the Hall sensor 10 will output a signal correspondingly so to realize control of the knob screen device. Alternatively, an annular light-leading friction shim 07 is provided in between the semi-transparent turning structure 04 and the mainboard 08, so as to relieve part damage due to direct friction.

Alternatively, at least one feedback vibration motor 09 is provided on the mainboard 08, and is provided at the same side as the at least one Hall sensor 10 so as to improve user experience.

Further, the magnetic attraction assembly 11 comprises: a magnetic attraction panel 112, a dimension of which is adapted to be a dimension of the mainboard 08; a magnetic attraction seat 114, provided on the magnetic attraction panel 112.

Further, the magnetic attraction assembly 11 further comprises a magnetic attraction pedestal 116 with a size adaptive to 86-type switch boxes, in some embodiments, the magnetic attraction assembly 11 comprises usually a plug of a magnetic connector provided on the magnetic attraction pedestal 116, and the plug is configured to be detachably connected with the 86-type switch boxes. An offline voice identification module and a temperature and humidity sensor are provided on the magnetic attraction pedestal 116. In this way the knob screen device supports offline phonetic function.

Further, a plurality of holes 1162 are provided on the magnetic attraction pedestal 116, and annular extrusions 1122 engaging with the plurality of holes one by one are provided on the magnetic attraction panel 112.

Further, at least one step screw 118 is provided on the magnetic attraction assembly 11, and the at least one step screw 118 passes the annular extrusions and the plurality of holes 1162 so as to fix the magnetic attraction pedestal 116 and the magnetic attraction panel 112.

As shown in FIG. 2, wherein an example is shown, the knob screen device in the present invention is attached to an 86-type switch box, and the entire device is of tight structures, tidy appearance and detachable.

In the present invention, the parts and elements that do not contribute directly to the technical solutions of the present invention are not elaborated here.

It is comprehensible that with the special echo chamber structure, pickup sound holes are hidden while better voice control sensitivity is achieved, a plurality of control manners such as touch control, knob, key, voice are available, multiple interaction and feedback functions such as vibration and lights are provided, and with the magnetic attraction assembly, convenient repeated plugging and detaching operations are possible when contact remains intact. Installation methods of magnetic attraction is to fix the entire knob screen device in pedestals of the 86-type switch boxes or install the same in other application circumstances such as fans, water heaters.

It shall be understood that, for the knob screen device as provided in the present invention, compared with the prior art, by the use of the annular multipolar flexible magnet and engagement thereof with the Hall sensor on the mainboard, every turning the knob screen device for an angle of a magnet pole, the Hall sensor will recognize corresponding pulse signals, so as to realize accurate and friction loss free control. With the magnetic attraction assembly, installation and detachment of the entire device is simpler and quick, adaptive to more usage circumferences, the entire device has simple structures, so that production cost can be reduced efficiently and it is easy to manufacture the device.

In view of the embodiments provided in the present invention, it shall be comprehensible that the method and structures disclosed herein can be realized in other methods. For example, the foregoing structural embodiments are only illustrative, when implementing the present invention, there can be different ways to categorize the structures, for example, a plurality of units or structures can be combined or integrated to another system, or some features can be neglected, or not executed.

The foregoing are only embodiments of the present invention, and are not intended to limit the protection scope of the present invention, equivalent replacement made based on the contents of the description and the drawings within the idea of the present invention, or direct or indirect use of the present invention in other related technical fields are covered in the protection scope of the present invention.

1. A knob screen device, comprising: a glass touch cover plate, a display, a display support, a semi-transparent turning structure, at least one annular light-leading friction shim, at least one battery, a mainboard, and a magnetic attraction assembly, wherein
the knob screen device further comprises:
at least one Hall sensor, provided on the mainboard;
at least one multicolor LED ambient light, provided on the mainboard;
at least one annular multipolar flexible magnet, provided in the semi-transparent turning structure; and
the semi-transparent turning structure is connected external components via the magnetic attraction assembly.

2. The knob screen device according to claim 1, wherein
an annular groove is provided in the semi-transparent turning structure and the annular groove is configured to fix the at least one annular multipolar flexible magnet.

3. The knob screen device according to claim 1, wherein
the at least one Hall sensor and the at least one annular multipolar flexible magnet are provided at a side of the mainboard.

4. The knob screen device according to claim 2, wherein
at least one annular light-leading friction shim is provided in between the semi-transparent turning structure and the mainboard.

5. The knob screen device according to claim 3, wherein
at least one feedback vibration motor is provided on the mainboard, and the at least one feedback vibration motor is provided at the same side of the at least one Hall sensor.

6. The knob screen device according to claim 1, wherein
the magnetic attraction assembly comprises:
at least one magnetic attraction panel, a dimension of which is adaptive to a shape and dimension of the mainboard;
at least one magnetic attraction seat, provided on the at least one magnetic attraction panel.

7. The knob screen device according to claim 6, wherein
the magnetic attraction assembly further comprises a magnetic attraction pedestal adaptive to 86-type switch boxes, and is configured to be detachably connected with the 86-type switch boxes;
an offline voice recognition module and a temperature and humidity sensor are provided on the magnetic attraction pedestal;
an annular reflective structure is formed in between the at least one magnetic attraction panel and the magnetic attraction pedestal so to enhance reception of voice signals.

8. The knob screen device according to claim 7, wherein
a plurality of holes are provided on the magnetic attraction pedestal and annular extrusions lockable with the plurality of holes one by one are provided on the magnetic attraction panel.

9. The knob screen device according to claim 8, wherein
at least one step screw is provided in the magnetic attraction assembly, wherein the at least one step screw passes the annular extrusions and the plurality of holes to further fix the mainboard and the display support.
